(19) United States
(12) Patent Application Publication
(10) Pub. No.: US 2013/0093013 A1
(43) Pub. Date: Apr. 18, 2013

(54) HIGH VOLTAGE TRANSISTOR AND MANUFACTURING METHOD THEREFOR

(71) Applicant: Hee Bae Lee, Seoul (KR)

(72) Inventor: Hee Bae Lee, Seoul (KR)

(73) Assignee: Dongbu HiTek Co., Ltd., Seoul (KR)

(21) Appl. No.: 13/463,143

(22) Filed: May 3, 2012

(30) Foreign Application Priority Data
Oct. 14, 2011 (KR) 10-2011-0105111

(51) Int. Cl. H01L 29/78; H01L 21/336

(52) U.S. Cl. 257/335; 438/197; 257/E29.256; 257/E21.409

(57) ABSTRACT

A high-voltage transistor may include a semiconductor substrate, and a gate electrode formed on and/or over the semiconductor substrate. Further, the high-voltage transistor may include source/drain regions formed on and/or over the semiconductor substrate at one side of the gate electrode, and impurity layers having a super junction structure and formed on and/or over a boundary of a drift region disposed below the gate electrode.

The present invention claims priority to Korean Patent Application No. 10-2011-0105111 (filed on Oct. 14, 2011), which is hereby incorporated by reference in its entirety.

### BACKGROUND

Generally, a high-voltage transistor may include a gate, a channel formed under the gate, source/drain regions formed on both sides of the channel, and a drift region for distributing an electric field applied to the source/drain regions at the time a device is driven.

Such a drift region may surround the source/drain regions while maintaining the distance between the boundary of the drift region and the boundary of the source/drain regions at a predetermined distance in order to distribute an electric field applied to the source/drain regions at the time of driving a semiconductor device such as a transistor or the like. Therefore, the electric field applied to the source/drain regions at the time of driving a semiconductor device may be distributed to the drift region, thus enhancing the voltage characteristics of breakdown attributable to the concentration of an electric field.

However, there is a problem in that the width of the drift region of a high-voltage transistor must be increased in order to increase the voltage capacity thereof, and thus the size thereof is increased.

FIG. 1 illustrates the structure of a related art high-voltage transistor. As illustrated in FIG. 1, it can be seen that the high-voltage transistor of the related art may be configured such that a gate electrode 100 is spaced apart from a drain electrode 102 by a predetermined distance.

In such a drain extended structure, when a high bias voltage is applied to the drain electrode 102, there is a problem in that an electric field concentrates on the boundary 104 of a drift region, thus causing breakdown.

### SUMMARY

Accordingly, embodiments have been devised to solve the above-mentioned and other problems, and an object is to provide a high-voltage transistor, in which P-type impurity layers and N-type impurity layers may be alternately formed in a drift region of the lower end of a gate electrode of the high-voltage transistor to form a P-N super junction structure, so that full depletion is caused by reverse bias with respect to each layer when a bias voltage is applied to a drain electrode, thereby increasing a breakdown voltage (BV) without increasing the size of the high voltage transistor, and a method of manufacturing the same.

In accordance with an embodiment, there is provided a high-voltage transistor, including at least one of: a semiconductor substrate; a gate electrode configured to be formed on and/or over the semiconductor substrate; source/drain regions formed on and/or over the semiconductor substrate at one side of the gate electrode; and impurity layers configured to be formed on and/or over a boundary of a drift region disposed below the gate electrode, wherein the impurity layers have a super junction structure.

The impurity layers may be formed by alternately ion-implanting N-type and P-type impurities.

Further, the impurity layers may be formed by horizontally laminating N-type and P-type impurities onto a boundary of the drift region.

Further, the impurity layers may be formed by sequentially laminating a first N-type impurity layer, a P-type impurity layer and a second N-type impurity layer.

Further, each of the impurity layers may have a thickness of about 0.5˜1.5 μm.

In accordance with an embodiment, there is provided a method for manufacturing a high-voltage transistor, including at least one of selectively ion-implanting an impurity into a semiconductor substrate to form a drift region; alternately ion-implanting N-type and P-type impurities on and/or over a boundary of the drift region to form impurity layers having a super junction structure; forming a field oxidation layer configured to define a device region on the semiconductor substrate; forming a gate electrode on and/or over the semiconductor substrate; forming spacers on and/or over both side walls of the gate electrode; and ion-implanting impurities onto the semiconductor substrate on both sides of the gate electrode to form source/drain regions.

The impurity layers may be formed by horizontally laminating N-type and P-type impurities onto a boundary of the drift region.

The forming the impurity layers may include at least one of: ion-implanting an N-type impurity into a boundary of the drift region to form a first N-type impurity layer, ion-implanting a P-type impurity onto the first N-type impurity layer to form a P-type impurity layer, and ion-implanting a N-type impurity onto the P-type impurity layer to form a second N-type impurity layer.

In accordance with the high-voltage transistor of embodiments, P-type impurity layers and N-type impurity layers may be alternately formed in a drift region of the lower end of a gate electrode of the high-voltage transistor to form a P-N super junction structure, so that full depletion is caused by reverse bias with respect to each layer when a bias voltage is applied to a drain electrode, thereby increasing a breakdown voltage without increasing the size of the high-voltage transistor.

### DRAWINGS

The objects and features of the embodiments will be more clearly understood from the following detailed description taken in conjunction with the accompanying drawings, in which:

FIG. 1 is a view illustrating the structure of a related art high-voltage transistor.

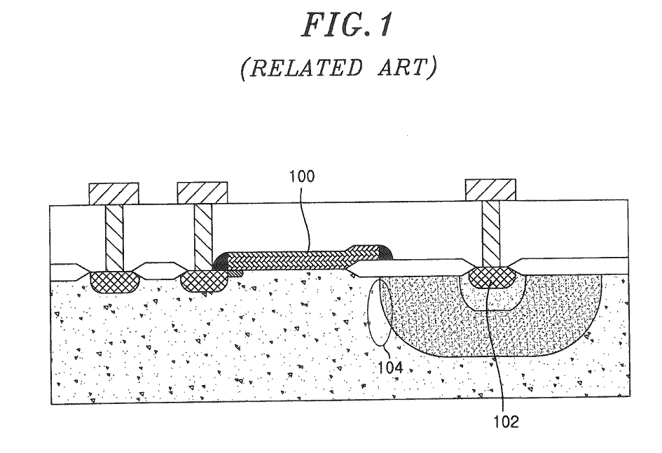

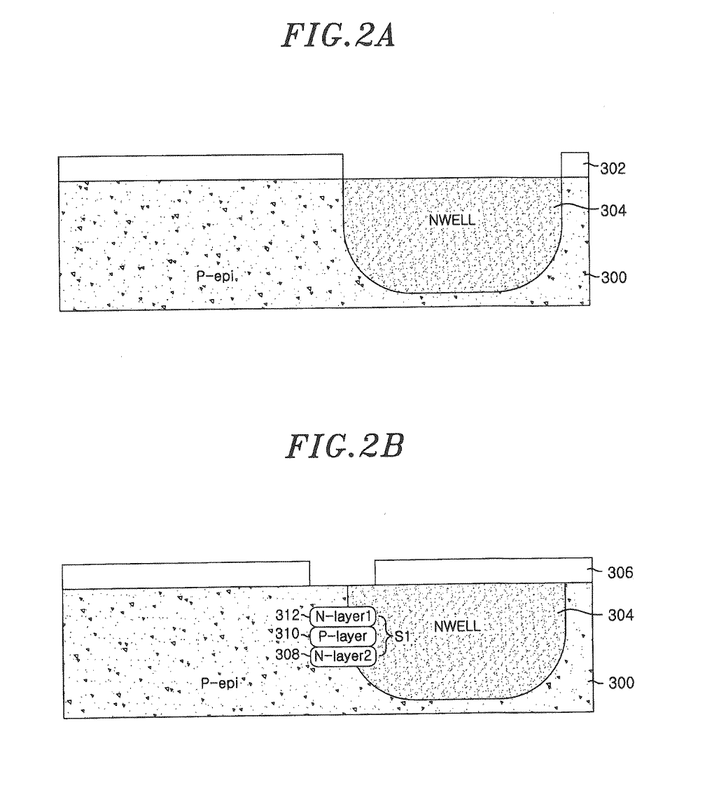

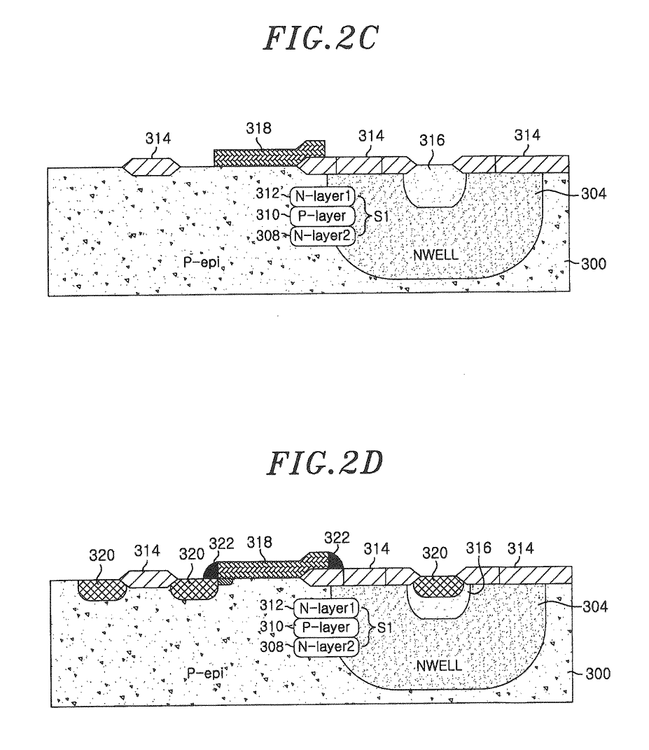

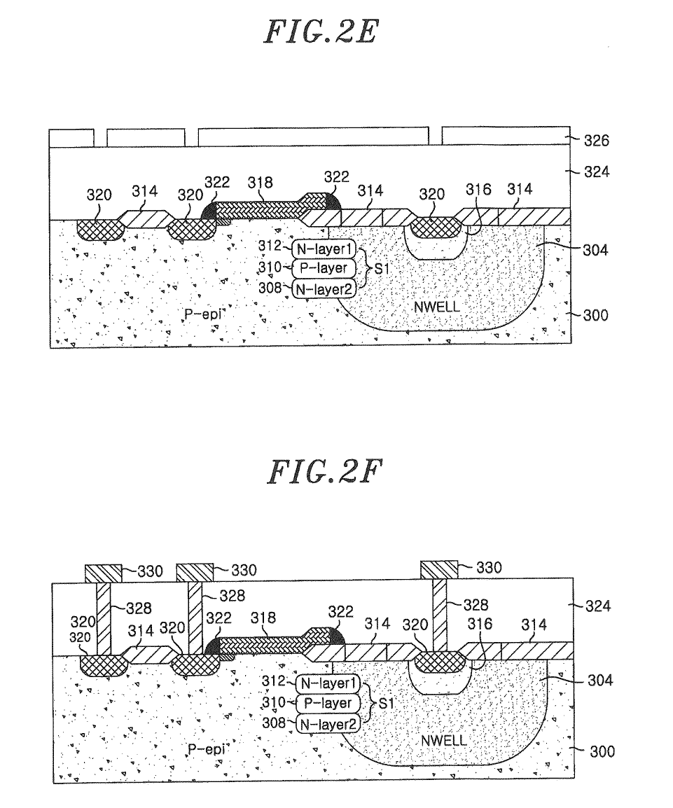

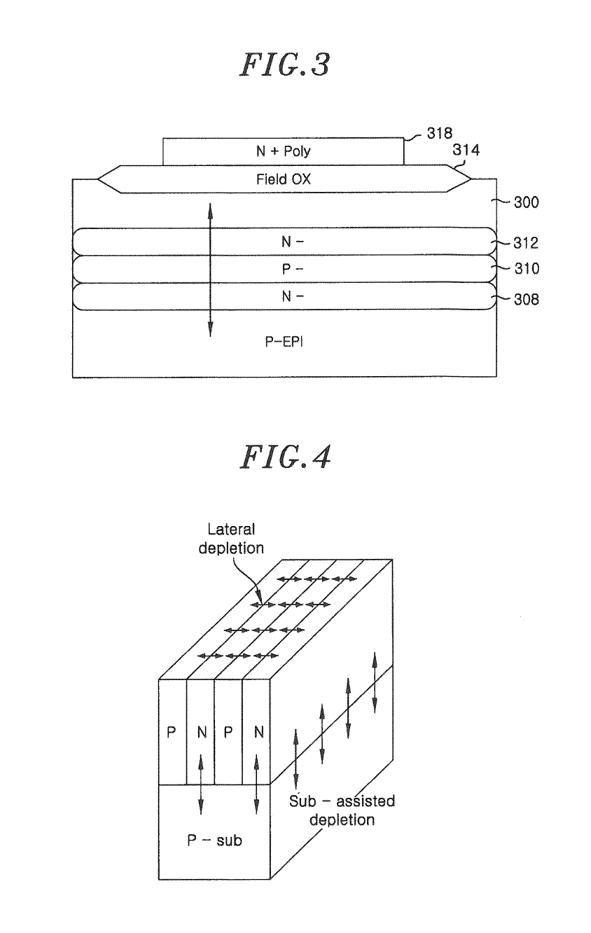

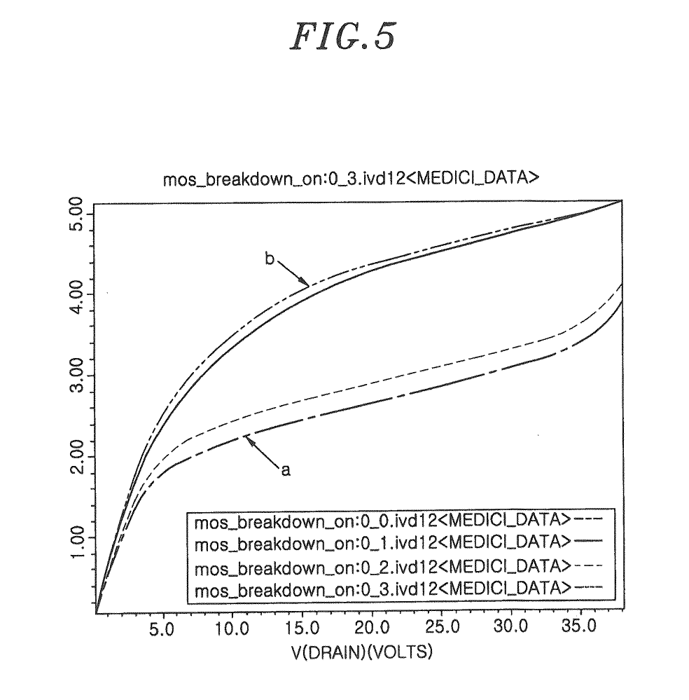

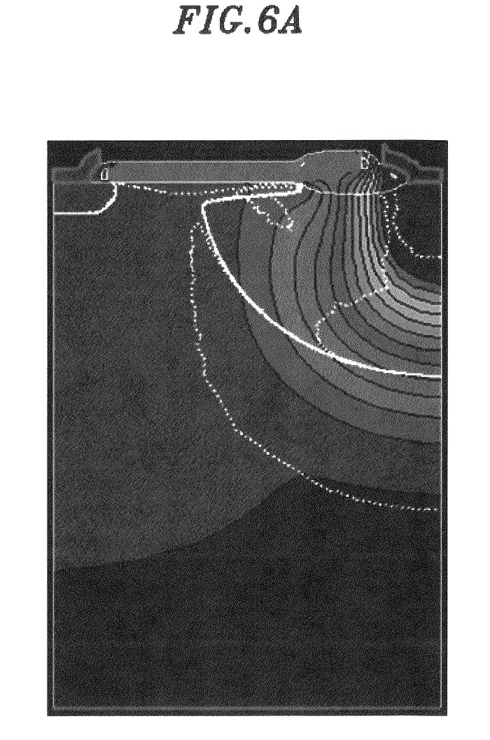

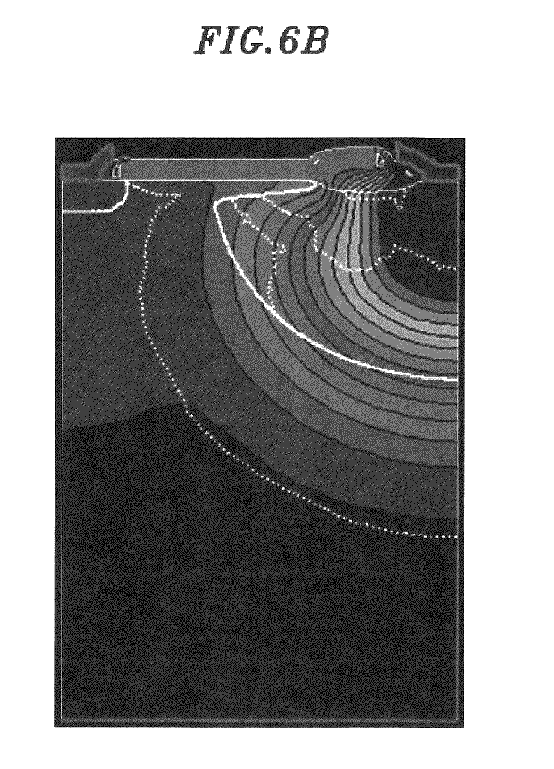

Example FIGS. 2A to 2F are views illustrating a process of manufacturing a high-voltage transistor according to embodiments.

Example FIG. 3 is a view illustrating a super junction structure according to embodiments.

Example FIG. 4 is a view illustrating the occurrence of lateral depletion in a super junction structure.

Example FIG. 5 is a graph illustrating the voltage-current characteristics in a drain electrode of high-voltage transistor according to embodiments.

Example FIGS. 6A and 6B are graphs illustrating the electric potential distribution characteristics of the high-voltage transistor according to embodiments and that of a related art high-voltage transistor.

### DESCRIPTION

Advantages and features of embodiments and methods of accomplishing the same may be understood more readily by reference to the following detailed description of embodiments and the accompanying drawings. Embodiments, however, may have many different forms and should not be construed as being limited to the embodiments set forth herein. Rather, these embodiments are provided so that this disclosure will fully convey the concepts to those skilled in the art, and the embodiments will only be defined by the appended claims. Like reference numerals refer to like elements throughout the specification.

In the following description of embodiments, if detailed description of already known structures and operations would confuse the subject matter of the present invention, such detailed description thereof will be omitted.

Hereinafter, embodiments will be described in detail with reference to the attached drawings.

Example FIGS. 2A to 2F are views illustrating a process of manufacturing a high-voltage. transistor according to embodiments. Hereinafter, the process of manufacturing a high-voltage transistor according to embodiments will be described in detail with reference to example FIGS. 2A to 2F.

First, as illustrated in example FIG. 2A, a photoresist may be applied onto a P-type semiconductor substrate (P-epi) 300, and then the photoresist may be patterned by photolithography to form a photoresist mask 302 defining a drift forming region.

Subsequently, an N-type impurity may be injected into the drift forming region of the semiconductor substrate 300 by ion implantation using the patterned photoresist mask 302, and then the N-type impurity may be diffused by thermal diffusion to form a drift region (Nwell) 304 on and/or over the semiconductor substrate 300.

Subsequently, as illustrated in example FIG. 2B, a photoresist may be further applied onto the semiconductor subs ate and patterned by photolithography to form a photoresist mask 306.

Subsequently, an N-type impurity, a P-type impurity and an N-type impurity may sequentially be ion-implanted on and/or over the boundary of the drift region 304 of the semiconductor substrate 300 using the photoresist mask 306 to form a second N-type impurity layer (N-layer 2) 308, a P-type impurity layer 310 and a first N-type impurity layer (N-layer 1) 3.12. As such, a P-N super junction structure (S1) may be vertically formed on and/or over the boundary of the -drift region 304 of the semiconductor substrate 300, so that full depletion may be caused by reverse bias with respect to each layer when a bias voltage is applied to a drain electrode, thereby forming the maximum depletion region.

Subsequently, as illustrated in example FIG. 2C, a field oxidation layer 314 may be formed on and/or over the semiconductor substrate 300, and then an activation region 316 may be formed at a position at which a drain electrode is to be formed, and a polysilicon layer may be formed on and/or over the semiconductor substrate 300. Thereafter, the polysilicon layer may be patterned to form a gate electrode 318.

Subsequently, as illustrated in example FIG. 2D, low-concentration impurities may be ion-implanted into source/drain regions located at both sides of the gate electrode 318 on the semiconductor substrate 300 to form LDD regions 320. Then, a nitride layer may be formed on the semiconductor substrate 300 and then etched to form spacers 322 on and/or over both side walls of the gate electrode 318.

Subsequently, as illustrated in example FIG. 2E, a pre-metal dielectric (PMD) liner may be deposited on and/or over the semiconductor substrate 300, and then a PSG layer may be deposited thereon to a predetermined thickness to form a PMD layer 324.

Thereafter, a photoresist may be applied onto the PMD layer 324, and then the photoresist may be patterned by photolithography to form a photoresist mask 326.

Subsequently, as illustrated in example FIG. 2F, the PMD layer 324 may be etched by reactive ion etching (RIE) using the photoresist mask 326, then the openings-of the etched PMD layer 324 may be charged with tungsten (W) to form contacts 328, and then metal lines 330 may be connected onto the contacts 328 to complete manufacture of a high-voltage transistor.

Example FIG. 3 is a sectional view illustrating a boundary of a drift region of a high-voltage transistor according to embodiments.

Referring to example FIG. 3, it can be seen that the N-type impurity layer 308, the P-type impurity layer 310 and the N-type impurity layer 312 may be alternately formed beneath the gate electrode 318 and the field oxidation layer 314 formed on and/or over the boundary of the drift region 304 of the semiconductor substrate 300, as illustrated in example FIG. 2A above.

This super junction structure formed beneath the lower end of the gate electrode 318 may be horizontally formed as compared to a super junction structure illustrated in example FIG. 4, and may have a similar structure of P/N/P/N but with horizontally formed impurity layers.

Therefore, when (+) bias is applied to a drain electrode, reverse bias is applied to each of the impurity layers, so that the total impurity layer region may be converted into a depletion region, thereby increasing the breakdown voltage of a drain electrode.

Further, the boundary between the drain electrode and the drift region may be enlarged, so that it may be possible to prevent an electric field from being concentrated on a specific position, thereby increasing the breakdown voltage thereof.

Example FIG. 5 is a graph illustrating the voltage-current characteristics in a drain electrode of the high-voltage transistor according to embodiments.

Referring to example FIG. 5, a super junction structure of P/N/P/N may be formed on and/or over the boundary of the drift region of the high-voltage transistor in accordance with embodiments. Therefore, comparing the voltage-current characteristic curve “a” in the drain electrode of a related art high-voltage transistor with the voltage-current characteristic curve “b” in the drain electrode of the high-voltage transistor in accordance with embodiments, it can be seen that the breakdown voltage of the drain electrode of the high-voltage transistor in accordance with embodiments may be increased and the current characteristics thereof may be improved as compared to the related art high-voltage transistor.

Example FIGS. 6A and 6B are graphs illustrating the electric potential distribution characteristics of the high-voltage transistor according to embodiments and a related art high-voltage transistor.

Here, example FIG. 6A is a graph illustrating the electric potential distribution characteristics in a drift region of a related art high-voltage transistor. As illustrated in example FIG. 6A, it can be seen that an electric field may be densely formed on and/or over the boundary of the drift region, and thus the electric field may be concentrated on the specific position. Therefore, as described above, there is a problem in that the breakdown voltage of a drain electrode may be lowered due to the concentration of the electric field.

Example FIG. 6B is a graph illustrating the electric potential distribution characteristics in a drift region of the high-voltage transistor having a super junction structure according to embodiments. As illustrated in example FIG. 6B, unlike that which is illustrated in example FIG. 6A, it can be seen that an electric field is relatively loosely formed on and/or over the boundary of the drift region, and thus the electric field may not be greatly concentrated on the specific position. Therefore, it can be seen that the breakdown voltage of a drain electrode may be increased, thus improving the characteristics of the high-voltage transistor.

While embodiments have been shown and described, it will be understood by those skilled in the art that various changes and modifications may be made without departing from the scope of the embodiments as defined in the following claims.

What is claimed is:

1. A high-voltage transistor, comprising:
a semiconductor substrate;
a gate electrode configured to be formed over the semiconductor substrate;
at least one of a source region and a drain region formed over the semiconductor substrate at one side of the gate electrode; and
impurity layers configured to be formed on a boundary of a drift region disposed below the gate electrode,
wherein the impurity layers have a super junction structure.

2. The high-voltage transistor of claim 1, wherein the impurity layers are formed by alternately ion-implanting N-type and P-type impurities.

3. The high-voltage transistor of claim 2, wherein the impurity layers are formed by horizontally laminating N-type and P-type impurities onto the boundary of the drift region.

4. The high-voltage transistor of claim 1, wherein the impurity layers are formed by sequentially laminating a first N-type impurity layer, a P-type impurity layer, and a second N-type impurity layer.

5. The high-voltage transistor of claim 4, wherein each of the impurity layers has a thickness of 0.5˜1.5 μm.

6. A method for manufacturing a high-voltage transistor, the method comprising:
selectively ion-implanting an impurity into a semiconductor substrate to form a drift region;
alternately ion-implanting N-type and P-type impurities at a boundary of the drift region to form impurity layers having a super junction structure;
forming a field oxidation layer configured to define a device region over the semiconductor substrate;
forming a gate electrode over the semiconductor substrate;
forming spacers on both side walls of the gate electrode; and
ion-implanting impurities onto the semiconductor substrate on both sides of the gate electrode to form at least one of a source region and a drain region.

7. The method of claim 6, wherein the impurity layers are formed by horizontally laminating N-type and P-type impurities onto the boundary of the drift region.

8. The method of claim 6, wherein the forming the impurity layers comprises:
ion-implanting an N-type impurity into a boundary of the drift region to form a first N-type impurity layer;
ion-implanting a P-type impurity onto the first N-type impurity layer to form a P-type impurity layer; and
ion-implanting an N-type impurity onto the P-type impurity layer to form a Second N-type impurity layer.

9. A high-voltage transistor comprising:
a semiconductor substrate;
one of a source region or a drain region formed over the semiconductor substrate;
a drift region formed in the semiconductor substrate and configured to partially surround the one of the source region or the chain region; and
a plurality of impurity layers formed on a boundary of the drift region.

10. The high-voltage transistor of claim 9, further comprising:
a gate electrode formed over the semiconductor substrate,
wherein the plurality of impurity layers is disposed below the gate electrode.

11. The high-voltage transistor of claim 9, wherein the impurity layers have a super junction structure.

12. The high-voltage transistor of claim 11, wherein the impurity layers comprise at least one N-type impurity layer and at least one P-type impurity layer configured in an alternating conductive type manner.

13. The high-voltage transistor of claim 12, wherein the impurity layers are formed by horizontally laminating the at least one N-type impurity layer and the at least one P-type impurity layer onto the boundary of the drift region.

14. The high-voltage transistor of claim 12, further comprising:
a gate electrode formed over the semiconductor substrate,
wherein the plurality of impurity layers is disposed below the gate electrode.

15. The high-voltage transistor of claim 11, wherein the impurity layers are formed by sequentially laminating a first N-type impurity layer, a P-type impurity layer, and a second N-type impurity layer.
